(19) United States
(12) Patent Application Publication
(10) Pub. No.: US 2010/0127302 A1
(43) Pub. Date: May 27, 2010

(54) LIGHT EMITTING DIODE PACKAGE

(75) Inventors: Tae Jun KIM, Pyeongtaek (KR); Young Suk Han, Suwon (KR); Won Ho Jung, Asan (KR)

Correspondence Address: MCDERMOTT WILL & EMERY LLP, 600 13TH STREET, N.W., WASHINGTON, DC, 20005-3096, US

(73) Assignee: SAMSUNG LED CO., LTD.

(21) Appl. No.: 12/570,703

(22) Filed: Sep. 30, 2009

(30) Foreign Application Priority Data
Nov. 27, 2008 (KR) 10-2008-0119099

(51) Int. Cl. H01L 33/00

(52) U.S. Cl. 257/99; 257/E33.066

(57) ABSTRACT

A light emitting diode package according to an aspect of the invention may include: a body receiving a light emitting diode; a lead electrically connected to the light emitting diode; and an adapter receiving a modified electrode electrically connected to the lead so that the polarity of the modified electrode is changed into the polarity of the lead, the adapter in which the body is received and fixed.

### CROSS-REFERENCE TO RELATED APPLICATIONS

This application claims the priority of Korean Patent Application No. 10-2008-0119099 filed on Nov. 27, 2008, in the Korean Intellectual Property Office, the disclosure of which is incorporated herein by reference.

### BACKGROUND OF THE INVENTION

1. Field of the Invention

The present invention relates to light emitting diode packages, and more particularly, to a light emitting diode package that can be mounted on an application without changing a lead pattern of the light emitting diode package when the light emitting diode package is connected to the application having leads whose number is different from that of the leads of the light emitting diode package.

2. Description of the Related Art

Light emitting diodes are semiconductor devices that generate light of various colors when a current is applied. When compared to filament-based light emitting devices, these light emitting diodes have a longer life span, low power consumption, excellent initial driving characteristics, high vibration resistance and high tolerance for repetitive power switching. Thus, there has been an increasing demand for light emitting diodes.

Recently, light emitting diode packages are being mounted onto various kinds of applications, such as vehicles, display boards or backlights. At this time, depending on the lead patterns of the applications, the number of leads in light emitting diode packages needs to be changed or light emitting diode packages need to be mounted onto different parts of the applications.

For example, when a light emitting diode has a lead including a two-terminal electrode consisting of an anode and a cathode, and a PCB of an application includes a four-terminal electrode consisting of three anodes and one cathode, the lead pattern of the light emitting diode package or the external electrode pattern of the PCB needs to be changed in order to provide an electrical connection.

In order to manufacture a light emitting diode package, a lead is disposed at the center of a mold, and molding materials are then injected into the mold. Therefore, a body has a larger thickness under the lead, which increases the thickness of the light emitting diode package.

### SUMMARY OF THE INVENTION

An aspect of the present invention provides a light emitting diode package that can be mounted to an application without changing a lead pattern of the light emitting package when the light emitting diode package is connected to an application having leads whose number is different from that of the leads of the light emitting diode package.

Another aspect of the present invention provides a light emitting diode package that is reduced in thickness by forming a lead, electrically connected to a light emitting diode, on the bottom of a body and connecting the body having the lead formed thereon to an adapter to thereby form a package.

According to an aspect of the present invention, there is provided a light emitting diode package including: a body receiving a light emitting diode; a lead electrically connected to the light emitting diode; and an adapter receiving a modified electrode electrically connected to the lead so that the polarity of the modified electrode is changed into the polarity of the lead, the adapter in which the body is received and fixed.

The lead may be an electrode extending from the bottom of the body to the edges thereof, and the modified electrode may include a conductive pad formed of conductive materials and a non-conductive pad formed of non-conductive materials so that the modified electrode is electrically connected to an external connection electrode.

A lead receiving groove may be provided within both sides of the adapter so that the lead is received in the lead receiving groove having the corresponding shape.

The adapter completely may cover the sides of the body.

The adapter may include a projection coupled and fixed to the top of the body being received.

A heat dissipation hole may be provided in a lower surface of the adapter.

A heat sink may be provided in the bottom of the adapter to dissipate heat generated from the light emitting diode.

According to an aspect of the present invention, there is provided a light emitting diode package including: a body having a lead electrically connected to a light emitting diode; and an adapter having the shape of a plate attached to the bottom of the body, and including a modified electrode allowing the lead to be electrically connected to an external connection electrode of an application having terminals whose number is different from the number of terminals of the lead.

The body and the adapter may have the same width.

The lead may be an electrode provided on a lower surface of the body, and the modified electrode includes three conductive pads formed of conductive materials and one non-conductive pad formed of non-conductive materials so that the modified electrode is electrically connected to the external connection electrode.

A heat dissipation hole may be provided in the lower surface of the adapter to dissipate heat generated from the light emitting diode.

A heat sink may be provided on the bottom of the adapter to dissipate heat generated from the light emitting diode.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating a light emitting diode package according to an exemplary embodiment of the invention;

FIG. 2 is an exploded perspective view illustrating the light emitting diode package, shown in FIG. 1;

FIG. 3 is a cross-sectional view illustrating the light emitting diode package, shown in FIG. 1, taken along the line A-A′;

FIG. 4 is a cross-sectional view illustrating the light emitting diode package, shown in FIG. 1, in which heat dissipation holes are formed;

FIG. 5 is a cross-sectional view illustrating the light emitting diode package, shown in FIG. 1, in which a heat sink is additionally formed;

FIG. 6 is a schematic perspective view illustrating a light emitting diode package according to another exemplary embodiment of the invention;

FIG. 7 is a cross-sectional view illustrating the light emitting diode package, shown in FIG. 6, taken along the line B-B′;

FIG. 8 is a cross-sectional view illustrating the light emitting diode package, shown in FIG. 6, in which heat dissipation holes are formed;

FIG. 9 is a cross-sectional view illustrating the light emitting diode package, shown in FIG. 6, in which a heat sink is formed; and

FIG. 10 is a schematic view illustrating how an adapter of a light emitting diode package according to an exemplary embodiment of the invention is connected to an external connection electrode.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art.

In the drawings, the same reference numerals will be used throughout to designate the same or like components.

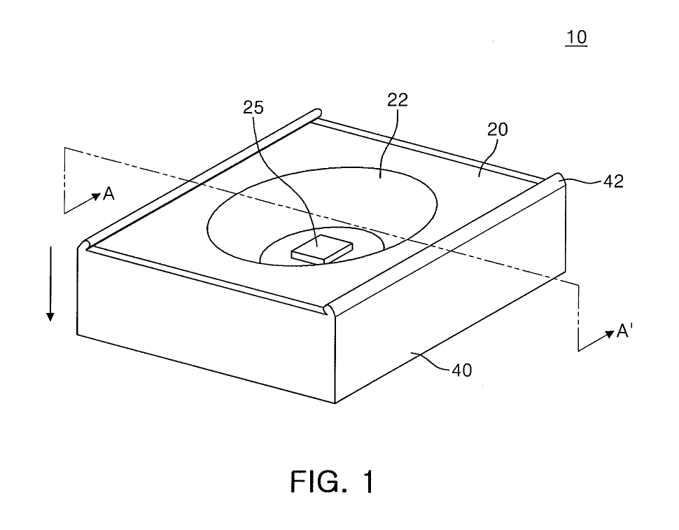

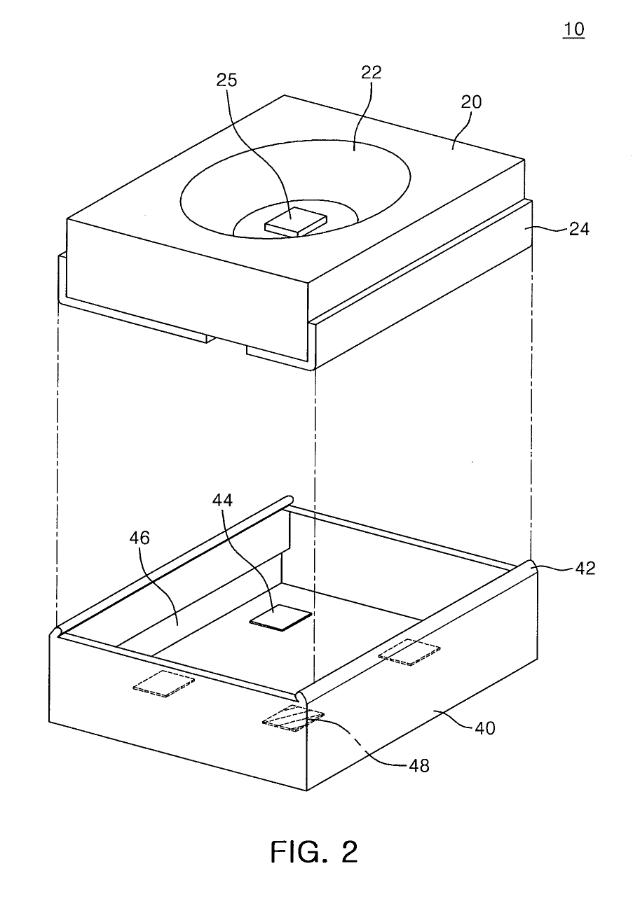

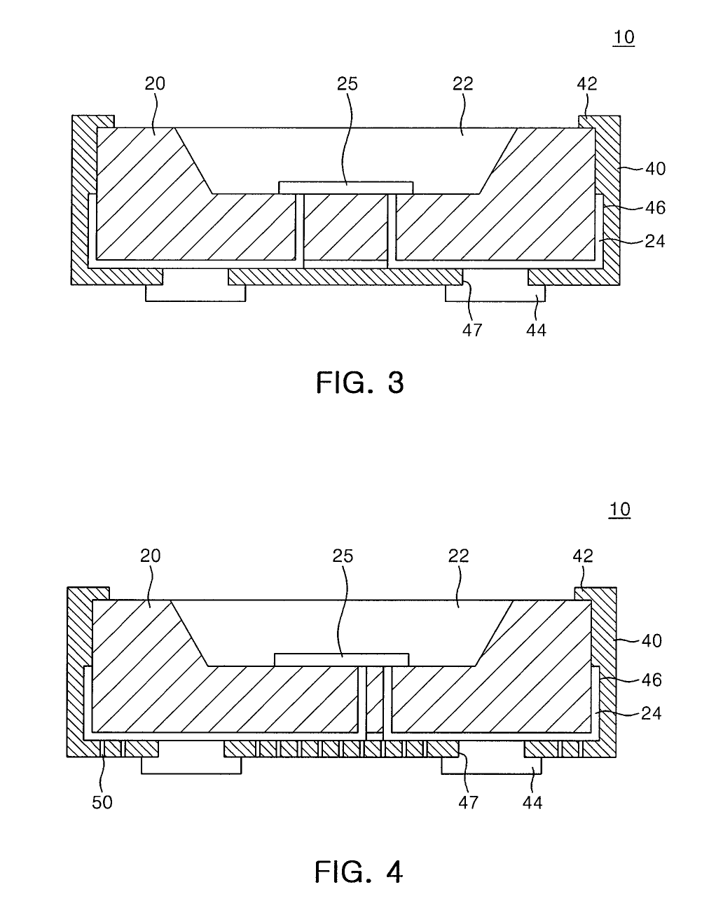

FIG. 1 is a schematic perspective view illustrating a light emitting diode package according to an exemplary embodiment of the invention. FIG. 2 is an exploded perspective view illustrating the light emitting diode package, shown in FIG. 1. FIG. 3 is a cross-sectional view illustrating the light emitting diode package, shown in FIG. 1, taken along the line A-A′.

Referring to FIGS. 1 through 3, a light emitting diode package 10 according to this embodiment includes a body 20, a lead 24 and an adapter 40.

A cavity 22 is formed within the body 20 so that a light emitting diode 25 can be mounted within the cavity 22. The body is formed of resin and may be manufactured by injection molding.

The light emitting diode 25 is electrically connected to the lead that extends from the lower part of the body 20 to the edges thereof. In the drawings, the light emitting diode is electrically connected to the lead 24 by chip bonding. However, the invention is not limited thereto. The light emitting diode 25 may be electrically connected to the lead 24 by wire bonding.

The lead 24 includes two electrodes consisting of anode (positive) polarity and cathode (negative) polarity. The lead 24 may be mounted onto the body 20, partially exposed to a lower surface of the body 20 and extend to the edges thereof. The larger the lead 24 is, the more heat generated from the light emitting diode can be dissipated. For this reason, it is preferable to manufacture a larger lead.

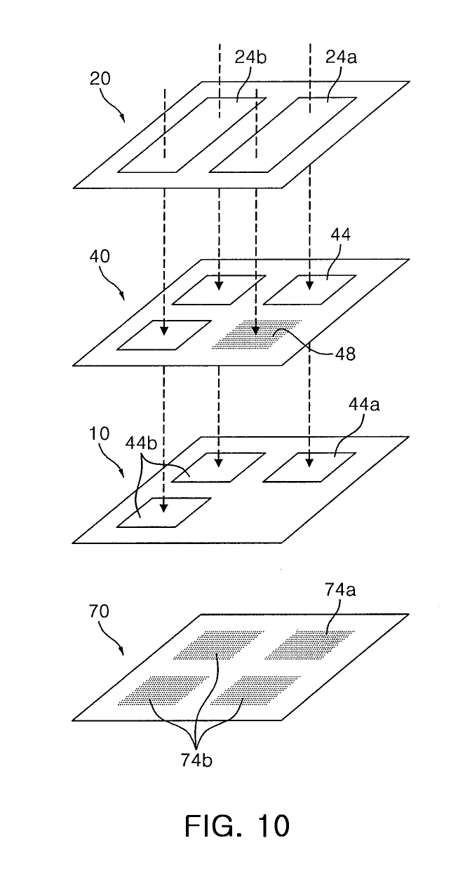

The adapter 40 has a modified electrode that is electrically connected to the lead 24 exposed to the bottom of the body 20. Here, the modified electrode has polarity that changes according to the polarity of the lead 24 so that the modified electrode has the same polarity as the lead 24. The adapter 40 accommodates the body 20, not exposing the sides of the body 20. The modified electrode is electrically connected to an external connection electrode (electrodes 74a and 74b in FIG. 10) of an application 70.

Particularly, when the external connection electrode of the application 70 is a four-terminal electrode (three anodes and one cathode), the modified electrode includes three conductive pads 44 formed of conductive materials and one non-conductive pad 48 formed of non-conductive materials that are formed on the adapter 40 so that the modified electrode is electrically connected to the external connection electrode.

Here, the number of leads and the number of terminals of the electrode connection electrode may be changed by a person skilled in the art.

A pad insertion hole 47 may be formed in the adapter 40 so that the conductive pad 44 or the non-conductive pad 48 may be inserted and fixed into the pad insertion hole 47.

The adapter 40 includes a projection 42 that is coupled to the top of the body 20 being received. Since the projection 42 is formed of materials having elasticity, the projection 42 opens when receiving the body 20, and closes after the body 20 is completely received.

The adapter 40 completely covers the edges of the body 20 to firmly support the body 20. Further, the adapter 40 may have a lead receiving recess 46 formed in both sides thereof so that the lead 24 can be received in the lead receiving recess 46 having the shape corresponding to the lead 24.

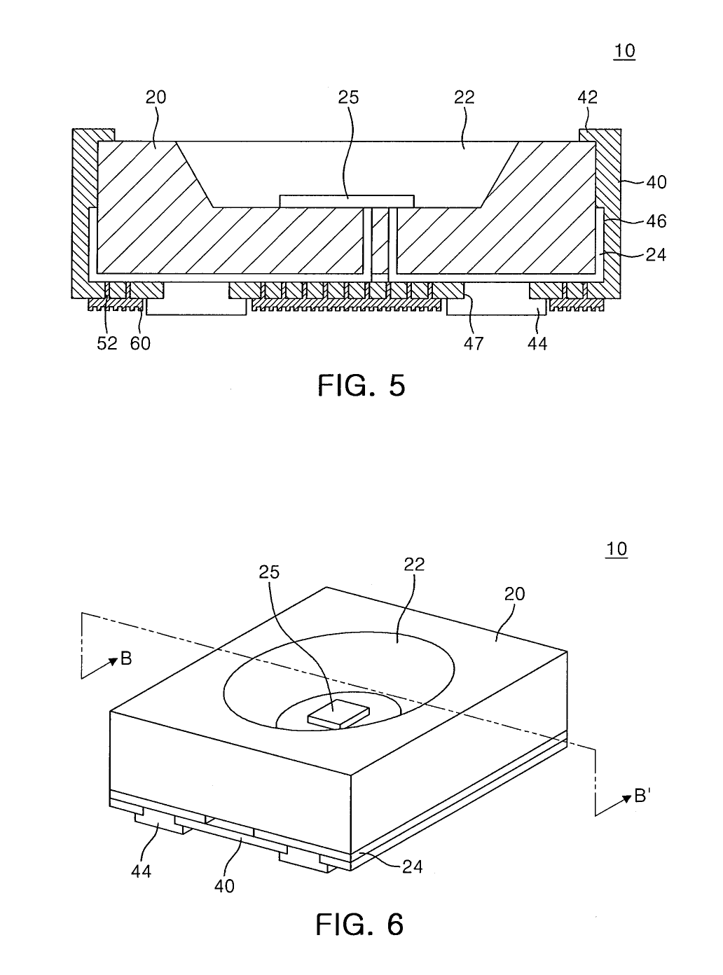

FIG. 4 is a cross-sectional view illustrating the adapter of the light emitting diode package, shown in FIG. 1, in which heat dissipation holes are formed. FIG. 5 is a cross-sectional view illustrating the adapter of the light emitting diode package, shown in FIG. 1, in which a heat sink is formed.

Referring to FIG. 4, heat dissipation holes 50 through which heat generated from the light emitting diode 25 is dissipated to the outside are formed in the bottom of the adapter 40 of the light emitting diode package 10.

The heat dissipation holes 50 may be evenly formed over the entire lower side of the adapter 40. Alternatively, the number of heat dissipation holes 50 formed in a region of the lower side of the adapter 40 that is adjacent to the be light emitting diode 25 may be greater than that of heat dissipation holes 50 formed in other regions.

Referring to FIG. 5, heat sink insertion holes 52 may be formed in the bottom of the adapter 40 of the light emitting diode package 10 so that a heat sink 60, including a metallic plate having excellent thermal conductivity, can be inserted into the heat sink insertion holes 52.

By the use of the heat sink 60, the area contacting the air increases to thereby dissipate heat generated from the light emitting diode to the outside.

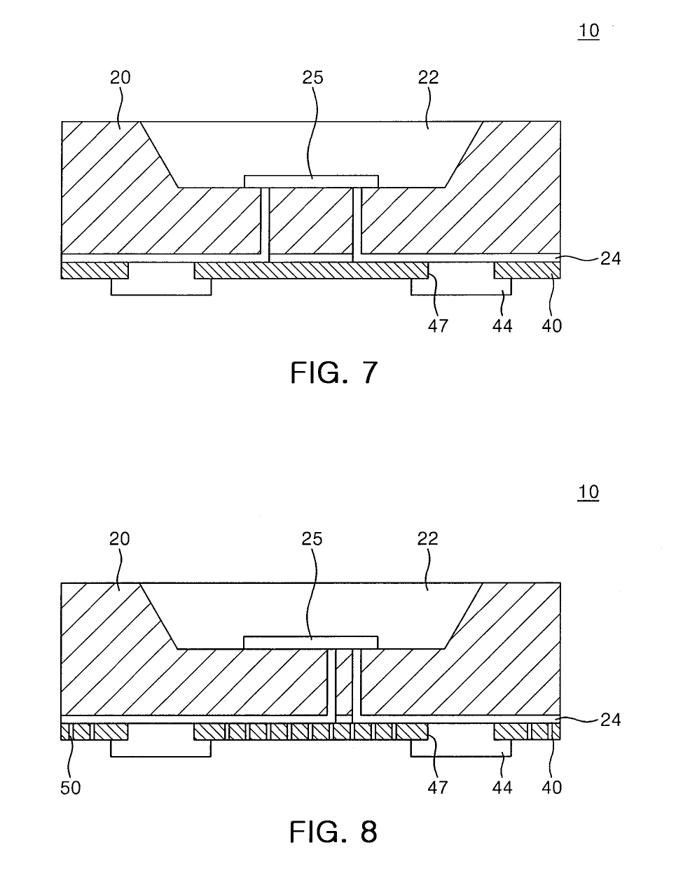

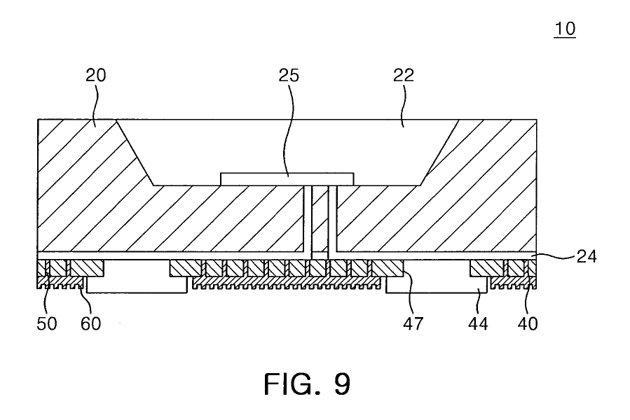

FIG. 6 is a schematic perspective view illustrating a light emitting diode package according to another exemplary embodiment of the invention. FIG. 7 is a cross-sectional view illustrating the light emitting diode package, shown in FIG. 6, taken along the line B-B′. FIG. 8 is a cross-sectional view illustrating an adapter of the light emitting diode package, shown in FIG. 6, in which heat dissipation holes are formed. FIG. 9 is a cross-sectional view illustrating the adapter of the light emitting diode package, shown in FIG. 6, in which a heat sink is formed.

Referring to FIGS. 6 through 9, the light emitting diode package 10 according to this embodiment may include the body 20 and the adapter 40.

The body 20 having the lead 24 electrically connected to the light emitting diode 25 according to this embodiment is the same as the body 20, as illustrated in the embodiment with reference to FIGS. 1 through 5. Thus, a detailed description thereof will be omitted.

The adapter 40 has the same width as the body 20. The adapter 40 does not completely cover the sides of the body 20 but is formed into a single plate that is attached to the lower surface of the body 20.

The body 20 and the adapter 40 have the same width. The lead 24 only extends along the lower surface of the body 20 but is not exposed to the edges of the body 20. As a result, the width of the light emitting diode package 10 is reduced along the axial direction to facilitate an electrical connection with the application.

The configurations of the heat sink 60 and the heat dissipation holes 50, formed in the bottom surface of the adapter 40, are the same as those of the embodiment illustrated in FIGS. 1 through 5. Thus, a detailed description thereof will be omitted.

FIG. 10 is a schematic view illustrating how an adapter of a light emitting diode package according to an exemplary embodiment of the invention is connected to an external connection electrode.

When the light emitting diode package 10 is mounted onto the application 70, such as a vehicle, a display board or a backlight, electrical connections between the lead 24 of the body 20, a modified electrode of the adapter 40, and an external connection electrode 74 of the application 70 will be described in detail with reference to FIG. 10.

The lead 24 of the body 20 includes a two-terminal electrode. The lead 24 includes a lead 24a having cathode polarity and a lead 24b having anode polarity.

The external connection electrode 74 of the application 70 is a four-terminal electrode and includes one electrode 74a having cathode polarity and three electrodes 74b having anode polarity.

The modified electrode of the adapter 40 includes one non-conductive pad 48 and three conductive pads 44 so that the modified electrode corresponds to the external connection electrode 74 of the application 70.

The adapter 40 and the body 20 are electrically connected to each other to form one light emitting diode package 10. The lead 24a, having cathode polarity, is electrically connected to the one of the conductive pads 44 and the one non-conductive pad 48 of the modified electrode, so that the polarity of the one conductive pad 44 is changed into cathode polarity. That is, the light emitting diode package 10 has one cathode electrode 44a.

Further, the lead 24b, having anode polarity, is electrically connected to the other two conductive pads 44 of the modified electrode, so that the polarity of each of the two conductive pads 44 is changed into anode polarity. That is, the light emitting diode package 10 has two anode electrodes 44b.

The two anode electrodes 44b of the light emitting diode package 10 are connected to the anode electrodes 74b of the application 70. The one cathode electrode 44a is connected to the cathode electrode 74a of the application 70.

The electrodes of the light emitting diode package 10 are electrically connected to the corresponding electrodes of the application 70. Therefore, electrodes having different numbers of terminals can be connected to each other without using a separate adapter.

As set forth above, in the light emitting diode package according to the exemplary embodiment of the invention, when the light emitting diode package is connected to an application having leads whose number is different from that of the leads of the light emitting diode package, the light emitting diode package can be easily mounted onto the application without changing a lead pattern of the light emitting diode package.

Furthermore, in the light emitting diode package according to the exemplary embodiment of the invention, an electrical connection can be made without mounting, depending on the arrangement of the external connection terminal of the application.

In addition, in the light emitting diode package according to the exemplary embodiment of the invention, the lead can be attached without molding to thereby facilitate the manufacturing of the light emitting diode package. Since the body is not formed under the bottom surface of the lead, the thickness of the light emitting diode package can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting diode package comprising:
a body receiving a light emitting diode;
a lead electrically connected to the light emitting diode; and
an adapter receiving a modified electrode electrically connected to the lead so that the polarity of the modified electrode is changed into the polarity of the lead, the adapter in which the body is received and fixed.

2. The light emitting diode package of claim 1, wherein the lead is an electrode extending from the bottom of the body to the edges thereof, and
the modified electrode comprises a conductive pad formed of conductive materials and a non-conductive pad formed of non-conductive materials so that the modified electrode is electrically connected to an external connection electrode.

3. The light emitting diode package of claim 1, wherein a lead receiving groove is provided within both sides of the adapter so that the lead is received in the lead receiving groove.

4. The light emitting diode package of claim 1, wherein the adapter completely covers the sides of the body.

5. The light emitting diode package of claim 1, wherein the adapter comprises a projection coupled and fixed to the top of the body being received.

6. The light emitting diode package of claim 1, wherein a heat dissipation hole is provided in a lower surface of the adapter.

7. The light emitting diode package of claim 1, wherein a heat sink is provided in the bottom of the adapter to dissipate heat generated from the light emitting diode.

8. A light emitting diode package comprising:
a body having a lead electrically connected to a light emitting diode; and
an adapter having the shape of a plate attached to the bottom of the body, and including a modified electrode allowing the lead to be electrically connected to an external connection electrode of an application having terminals whose number is different from the number of terminals of the lead.

9. The light emitting diode package of claim 8, wherein the body and the adapter have the same width.

10. The light emitting diode package of claim 8, wherein the lead is an electrode provided on a lower surface of the body, and
the modified electrode comprises three conductive pads formed of conductive materials and one non-conductive pad formed of non-conductive materials so that the modified electrode is electrically connected to the external connection electrode.

11. The light emitting diode package of claim 8, wherein a heat dissipation hole is provided in the lower surface of the adapter to dissipate heat generated from the light emitting diode.

12. The light emitting diode package of claim 8, wherein a heat sink is provided on the bottom of the adapter to dissipate heat generated from the light emitting diode.
